(19) United States
(12) Patent Application Publication
(10) Pub. No.: US 2010/0314150 A1
(43) Pub. Date: Dec. 16, 2010

(54) RF EQUIPMENT PROTECTION DEVICE AND MOUNTING METHOD FOR SAME

(76) Inventors: Yong-Gyu Song, Kyeonggi-do (KR); Seung-Chan Hong, Incheon-si (KR); Wook Choi, Incheon-si (KR); Sung-Soo Chung, Incheon-si (KR)

Correspondence Address: DUANE MORRIS LLP - Philadelphia;IP DEPARTMENT, 30 SOUTH 17TH STREET, PHILADELPHIA, PA, 19103-4196, US

(21) Appl. No.: 12/867,360

(22) PCT Filed: Feb. 13, 2009
(86) PCT No.: PCT/KR09/00725

§ 371 Date: Aug. 12, 2010

(30) Foreign Application Priority Data
Feb. 14, 2008 (KR) 10-2008-0013472

(51) Int. Cl. H02G 3/18; H05K 13/00

(52) U.S. Cl. 174/59; 29/525.02

(57) ABSTRACT

Disclosed are an RF equipment protection device and a mounting method for same. The RF equipment protection device of the present invention includes a main body with an open front end and an open rear end to accommodate RF equipment having an input/output connector, a first cover which is arranged to cover the front end of the main body, and having a connector hole for the passage of the front end side connector of the RF equipment, and a second cover which is arranged to cover the rear end of the main body, and has a connector hole for the passage of the rear end side connector of the RF equipment. The RF equipment protection device of the present invention is provided with a housing for accommodating the RF equipment, advantageously protecting the RF equipment in a stable manner and reducing manufacturing costs.

### TECHNICAL FIELD

The present invention relates to an RF equipment protection device and a method of mounting the RF equipment protection device. More particularly, the invention relates to an RF equipment protection device and a method of mounting the RF equipment protection device that can safely protect an RF equipment from the external environment and lower manufacturing costs.

### BACKGROUND ART

A mobile communication system may transfer signals by transmitting electromagnetic waves through the air. As such, when signals are received at the receiver end, a large amount of noise can be included.

Thus, a base transceiver station, etc., in a mobile communication system may include RF equipment such as a dielectric resonator filter, which removes such noise, and a TMA (tower mounted amplifier), which amplifies signals so that the wireless communication can be provided with greater stability.

As illustrated in FIG. 1, a dielectric resonator filter may include a housing 10 that has several cavities inside, with the dielectric resonator placed in a cavity inside the housing 10. Connectors 13 may be provided at the front and rear sides of the housing 10 for inputting and outputting signals, and a support 14 may be provided on the lower surface of the housing 10.

A TMA used in a mobile communication system is a device that is installed on a steel tower, on which a receiver antenna is located, instead of being included in the equipment of a BTS (base transceiver station). The TMA is also referred to as a TTL (tower-top LNA) or a TTLNA (tower-top low noise amplifier).

The TMA is designed to improve problems related to cable noise and noise created during the transfer of signals received by the receiver antenna to a base transceiver station's signal processing unit. The TMA may include a receiver filter and an LNA (low-noise amplifier) forming a single block that is installed on a steel tower in close proximity to the receiver antenna.

Similar to the dielectric resonator filter, the TMA may also include a housing for encasing the apparatus for amplification, as well as connectors for inputting and outputting signals.

In cases where such RF equipment are exposed to the external environment, a structure may be provided for protecting the RF equipment from the external environment, such as wind, moisture, etc., which can affect reception.

FIG. 1 illustrates the composition of an RF equipment protection device according to the related art.

Referring to FIG. 1, an RF equipment protection device according to the related art may include an upper cover 15 and a lower cover 16.

The upper cover 15 and lower cover 16 may be fastened by bolts to the upper and lower portions of an RF equipment. Here, a process of adding a silicone O-ring or a dispensing process can be performed to provide a more airtight seal.

According to the related art, however, the RF equipment protection device structure does not cover all of the surfaces of the RF equipment. So, a process of coating the perimeter of the RF equipment and afterwards of plating the equipment with a chromate, for example, may be required before assembly.

Here, applying a chromate may involve applying a rustproof coating by placing the RF housing in a solution containing a chromate or a dichromate as a main ingredient.

Thus, according to the related art, a separate process of coating and plating the RF equipment itself may be required before the assembly process, leading to an increased manufacturing cost and a more complicated manufacturing process. Furthermore, since the housing does not cover all of the surfaces of the RF equipment, there is still a risk of damage to the RF equipment.

### DISCLOSURE

### Technical Problem

To resolve the problems described above, an aspect of the invention is to provide an RF equipment protection device and a method of mounting the RF equipment protection device that can reduce manufacturing time and manufacturing cost.

### Technical Solution

To achieve the objective above, an aspect of the invention provides an RF equipment protection device that includes: a main body, configured to encase an RF equipment having input/output connectors, and having an open front end and an open rear end; a first cover, arranged at the front end of the main body and having a connector hole through which a front-side connector of the RF equipment passes; and a second cover, arranged at the rear end of the main body, and having a connector hole through which a rear-side connector of the RF equipment passes.

Another aspect of the invention provides a method of mounting an RF equipment protection device onto the RF equipment, where the an RF equipment protection device includes a main body, a first cover, and a second cover, and where the RF equipment includes input/output connectors. This method includes: inserting the RF equipment in the main body, which has an open front end and an open rear end; providing the first cover, which is configured such that the connectors on a front side of the RF equipment can pass through the first cover, at a front end of the main body; providing the second cover, which is configured such that the connectors on a rear side of the RF equipment can pass through the second cover, at a rear end of the main body; and providing nuts on the outwards sides of the first cover and the second cover and screw joining the nuts with screw threads formed on the front-side connectors and the rear-side connectors.

### ADVANTAGEOUS EFFECTS

According to an embodiment of the invention, the RF equipment protection device can safely protect the RF equipment as it encases all surfaces of the RF equipment.

Also, according to an embodiment of the invention, the RF equipment protection device can be fastened more securely by forming screw threads on the outwardly protruding connectors and applying nuts for screw-joining.

Furthermore, according to an embodiment of the invention, manufacturing costs can be reduced, as the RF equipment protection device can be manufactured by extrusion molding using a certain plastic material, and manufacturing efficiency can be increased, as the process of coating and plating the RF equipment can be omitted.

### DESCRIPTION OF DRAWINGS

FIG. 1 illustrates the composition of an RF equipment protection device according to the related art.

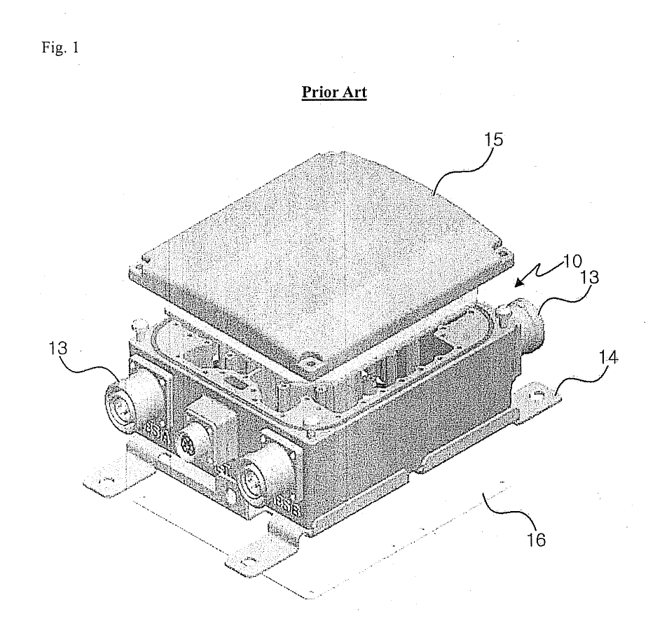

FIG. 2 is an exploded perspective view of an RF equipment and an RF equipment protection device according to an embodiment of the invention before assembly.

FIG. 3 is a perspective view of an RF equipment and an RF equipment protection device after assembly.

FIG. 4 is a diagram illustrating an extruding process for an RF equipment protection device according to an embodiment of the invention.

FIG. 5 is a cross-sectional view of a main body according to an embodiment of the invention.

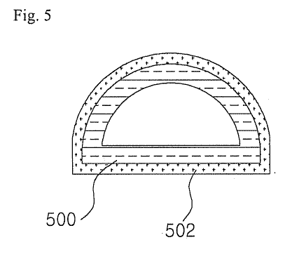

### MODE FOR INVENTION

As the present invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In describing the drawings, like numerals are used to refer to like elements.

When an element is mentioned to be “coupled” or “connected” to another element, this may mean that it is directly coupled or connected to the other element, but it is to be understood that yet another element may exist in-between. On the other hand, when an element is mentioned to be “directly coupled” or “directly connected” to another element, it is to be understood that there are no other elements in-between.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

Unless otherwise defined, all terms used herein, including technical or scientific terms, have the same meanings as those generally understood by those with ordinary knowledge in the field of art to which the present invention belongs. Such terms as those defined in a generally used dictionary are to be interpreted to have the meanings equal to the contextual meanings in the relevant field of art, and are not to be interpreted to have ideal or excessively formal meanings unless clearly defined in the present application.

Certain embodiments of the invention will be described below in more detail with reference to the accompanying drawings. For better understanding, the same elements are indicated by the same numerals regardless of the figure number.

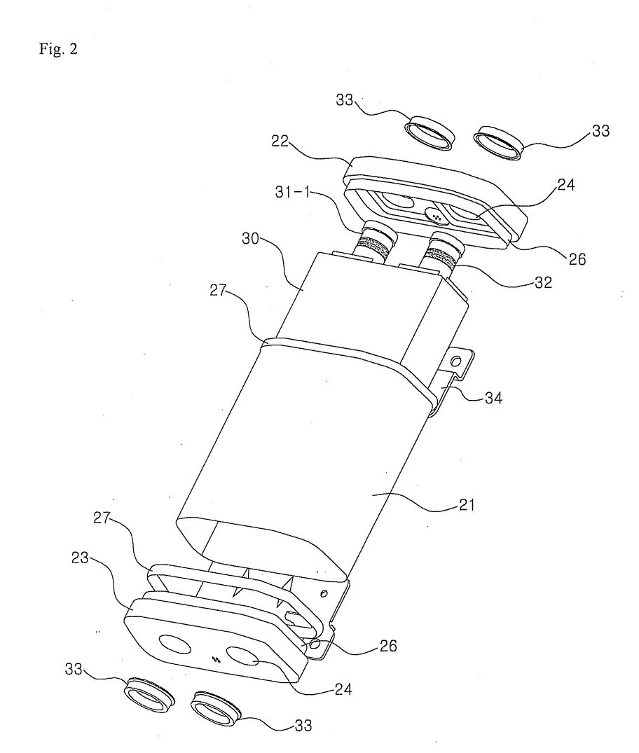

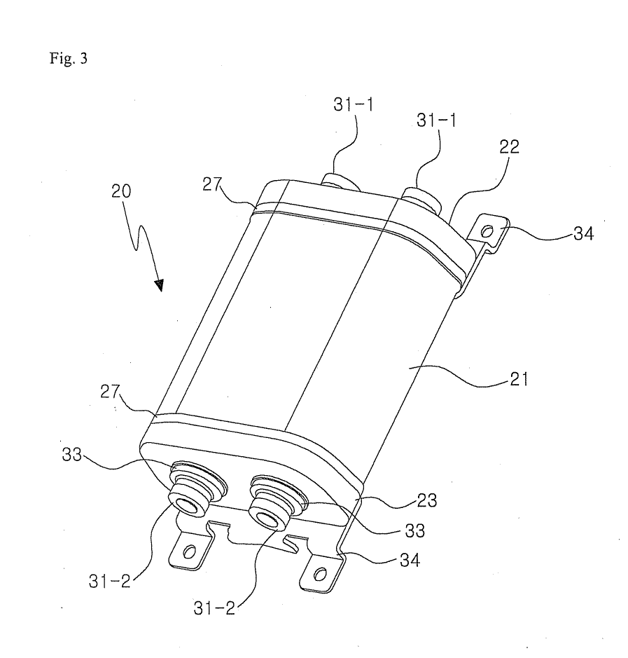

FIG. 2 is an exploded perspective view of an RF equipment and an RF equipment protection device according to a preferred embodiment of the invention before assembly, and FIG. 3 is a perspective view of an RF equipment and an RF equipment protection device after assembly.

As illustrated in FIG. 2 and FIG. 3, an RF equipment protection device 20 may include a main body 21, a first cover 22, and a second cover 23, to encase the RF equipment 30.

The RF equipment 30 applied to the present invention may be an equipment for removing noise from the signals exchanged in mobile communication and for amplifying such signals, etc., and can encompass all types of equipment that includes the circuitry and mechanical composition necessary for signal processing as well as connectors for inputting and outputting signals as described below.

The main body 21, first cover 22, and second cover 23 may be made from a plastic material and may be manufactured by extrusion molding, in consideration of the size of the RF equipment 30.

The RF equipment protection device 20 may be used to protect the RF equipment from the external environment.

According to an embodiment of the invention, the main body 21 for encasing the RF equipment 30 may preferably be made of a material that is not high in permittivity, in consideration of the electromagnetic waves that propagate within the RF equipment 30.

The main body 21 according to an embodiment of the invention can be made from polycarbonate (PC), PC/SBS (styrene butadiene styrene), ABS (acrylonitrile butadiene styrene) copolymer resin, Noryl resin, or PVC (polyvinyl chloride), which have desirable strength characteristics.

Also, the main body 21 of an RF equipment protection device 20 according to an embodiment of the invention can further include a skin made from PC/ASA (acrylonitrile styrene acrylate) or weatherproof PC, or more preferably ASA resin, to serve as a protective skin against ultraviolet rays.

While the above describes only the material for the main body 21, it is apparent to the skilled person that the first cover 22 and second cover 23 can also be made from the same material as that of the main body 21.

The front end and rear end of the main body 21 can be open, enabling it to encase the RF equipment 30, and the size of the main body 21 can be such that allows it to encase the RF equipment 30.

Generally, one or more connectors 31-1, 31-2 (collectively referred to by the numeral “31”) for inputting and outputting signals may be provided on the RF equipment 30. On each of the first cover 22 and second cover 23 according to an embodiment of the invention, connector holes 24 may be provided that correspond with these connectors 31.

That is, the connector holes 24 of the first cover 22 may be provided for the front-side connectors 31-1 of the RF equipment located at the front side of the main body 21, while the connector holes 24 of the second cover 23 may be provided for the rear-side connectors 31-2 of the RF equipment 30.

According to an embodiment of the invention, the installation may involve encasing the RF equipment 30 within the main body 21 described above and afterwards placing the first cover 22 and the second cover 23 on the front and rear ends of the main body 21.

Here, each connector 31-1, 31-2 of the RF equipment 30 may pass through the connector holes 24 formed in the first cover 22 and second cover 23, and a portion of each connector 31 may protrude outward from each cover 22, 23 on opposing sides of the main body 21 described above.

On each of the first cover 22 and the second cover 23, on the side facing the main body 21, an insertion part 26 may be formed that is to be inserted inside the main body 21. To maintain an airtight seal between the first cover 22 and second cover 23 and the main body 21, a silicone band 27 may be provided between the front end of the main body 21 and the first cover 22 and between the rear end of the main body 21 and the second cover 23.

Here, in one side of the silicone band 27, a groove may be formed that corresponds with the shape of the front end and rear end of the main body 21 such that the silicone band 27 may be fit onto the entire front end and rear end of the main body 21 by way of the groove.

Preferably, the size of the inner perimeter of the silicone band 27 may be somewhat smaller than the size of the outer perimeter of the insertion part 26. In this case, the insertion part 26 of the first cover 22 and second cover 23 may be press-fitted into the silicone band 27, and thus into the main body 21, to ensure airtightness in the RF equipment protection device 20.

In a preferred embodiment of the invention, an anti-detachment structure may be provided on the connectors 31, in order to prevent the first cover 22 and second cover 23 from becoming detached from the main body 21.

As illustrated in FIG. 2, a screw thread 32 may be formed on each connector 31 of the RF equipment according to an embodiment of the invention.

As described above, a portion of each connector 31 may pass through a connector hole 24 formed in the first cover 22 and second cover 23, and the screw thread 32 according to an embodiment of the invention may be formed on a portion of an area protruding through the connector hole 24.

Preferably, the screw thread 32 of the connector 31 can be formed by a particular length at a portion that protrudes outwards from the first cover 22 and second cover 23 when the RF equipment 30 is encased in the RF equipment protection device 20.

According to an embodiment of the invention, nuts 33 may be provided at the outer sides of the first cover 22 and second cover 23 in a number corresponding to that of the connectors 31, and the RF equipment protection device 20 may be joined with the RF equipment 30 by screw-joining the nuts 33 to the screw threads 32.

A support 34 may be provided on one surface of the RF equipment protection device 20, where the support 34 may be used to join the RF equipment protection device 20 to a base transceiver station, etc.

While it is not illustrated in the drawings, an embodiment of the invention can additionally include O-rings on the connectors 31 of the RF equipment 30 to increase airtightness between the connectors 31 and the body of the RF equipment 30.

Thus, according to an embodiment of the invention, the RF equipment protection device 20 is provided to cover all surfaces of the RF equipment. As such, the process of coating and applying chromate treatment on exposed surfaces of the RF equipment, as is common in the related art, can be omitted, leading to reduced manufacturing costs, distribution costs, etc.

Moreover, since the RF equipment protection device can be manufactured by extrusion molding using a plastic material, manufacturing costs can be further reduced.

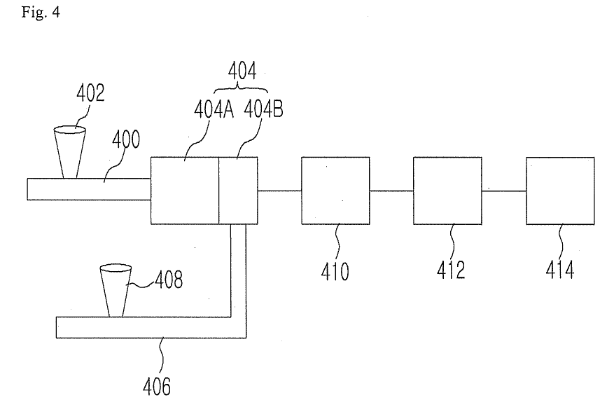

FIG. 4 is a diagram illustrating an extruding process for an RF equipment protection device according to an embodiment of the invention.

For easier explanation, the following descriptions will focus on the procedure for extrusion molding the main body 21 of the RF equipment protection device 20, using an example in which the main body 21 according to an embodiment of the invention includes an inner skin 500 and a UV-protective skin 502.

Referring to FIG. 4, a system for he extrusion molding process may include feeders 400, 406, hoppers 402, 408, casts 404, a molding unit 410, a transport unit 412, and a cutting unit 414.

The feeders 400, 406 may transport the resins that are fed through the hoppers 402, 408. To be more specific, a first feeder 400 may transport a polycarbonate (PC) resin, which is fed through a first hopper 402, to a first cast 404A. Also, a second feeder 406 may transport an ASA resin, which is fed through a second hopper 408, to a second cast 404B.

The casts 404 may fashion the transported polycarbonate (PC) resin and ASA resin to correspond to a cast of a particular shape, and thereby produce the structure of a main body 21 in a desired shape, such as that shown in FIG. 2, for example. However, the shape and dimensions of the main body structure formed at this stage is as yet in an incomplete state.

The molding unit 410 may serve to fashion the incomplete cover structure into a desired shape and dimensions, i.e. to mold the incomplete main body structure into a complete state. Then, the molding unit 410 may transport the molded main body structure to the cutting unit 414 by way of the transport unit 412.

The transport unit 412 may include means for transporting the molded main body structure such as a roller arrangement, for example. Of course, the transport unit 412 can also use robots for transporting the molded main body structure.

The cutting unit 414 may cut the cover structure transported by the transport unit 412 into a desired size and shape to form the main body 21, such as that shown in FIG. 2.

While the spirit of the invention has been described in detail with reference to particular embodiments, the embodiments are for illustrative purposes only and do not limit the invention. It is to be appreciated that those skilled in the art can make various changes, modifications, and additions to the embodiments without departing from the spirit and scope of the invention and that such changes, modifications, and additions are encompassed by the scope of claims appended below.

1. An RF equipment protection device comprising:
a main body configured to encase an RF equipment having input/output connectors, the main body having an open front end and an open rear end;
a first cover arranged at the front end of the main body, the first cover having a connector hole through which a front-side connector of the RF equipment passes; and
a second cover arranged at the rear end of the main body, the second cover having a connector hole through which a rear-side connector of the RF equipment passes.

2. The RF equipment protection device of claim 1, wherein the RF equipment protection device is manufactured by extrusion molding.

3. The RF equipment protection device of claim 1, wherein an insertion part is formed on each of the first cover and the second cover on a side thereof facing the main body, the insertion part configured to be inserted inside the main body.

4. The RF equipment protection device of claim 3, wherein a silicone band for maintaining airtightness is interposed between the insertion part and the main body.

5. The RF equipment protection device of claim 4, wherein the silicone band has a groove formed in one side thereof, the groove configured to fit onto the front end and the rear end of the main body.

6. The RF equipment protection device of claim 1, wherein there are one or more front-side connectors and one or more rear-side connectors,
and wherein the front-side connectors and the rear-side connectors have a screw thread formed on a portion thereof.

7. The RF equipment protection device of claim 6, wherein the screw thread is formed on an area of the front-side connector protruding through the first cover and on an area of the rear-side connector protruding through the second cover, and wherein a nut is screw-joined with the screw thread.

8. The RF equipment protection device of claim 1, wherein the main body comprises an inner skin and a UV-protective skin arranged over the inner skin to block ultraviolet rays.

9. The RF equipment protection device of claim 8, wherein the inner skin contains at least one of polycarbonate (PC), PC/SBS (styrene butadiene styrene), ABS (acrylonitrile butadiene styrene) copolymer resin, Noryl resin, and PVC (polyvinyl chloride), or a combination thereof.

10. The RF equipment protection device of claim 8, wherein the UV-protective skin contains at least one of ASA resin, PC/ASA, and weatherproof PC.

11. A method of mounting an RF equipment protection device onto an RF equipment, wherein the RF equipment protection device comprises a main body, a first cover, and a second cover, and wherein the RF equipment comprises input/output connectors, the method comprising:
inserting the RF equipment in the main body, the main body having an open front end and an open rear end;
providing the first cover at a front end of the main body, the first cover configured such that the connectors on a front side of the RF equipment pass therethrough;
providing the second cover at a rear end of the main body, the second cover configured such that the connectors on a rear side of the RF equipment pass therethrough; and
providing nuts on outwards sides of the first cover and the second cover and screw-joining the nuts with screw threads formed on the front-side connectors and the rear-side connectors.
